(19) United States
(12) Patent Application Publication
(10) Pub. No.: US 2025/0228102 A1
(43) Pub. Date: Jul. 10, 2025

(54) DISPLAY DEVICE INCLUDING SEPARATORS ON ANODE ELECTRODES

(71) Applicant: SAMSUNG DISPLAY CO., LTD., YONGIN-SI (KR)

(72) Inventors: Sung Gwon MOON, Yongin-si (KR); Woo Geun LEE, Yongin-si (KR); Dong Han KANG, Yongin-si (KR); Jee Hoon KIM, Yongin-si (KR); Seung Sok SON, Yongin-si (KR); Shin Hyuk YANG, Yongin-si (KR)

(21) Appl. No.: 18/939,659

(22) Filed: Nov. 7, 2024

(30) Foreign Application Priority Data
Jan. 10, 2024 (KR) 10-2024-0004183

(51) Int. Cl. H10K 59/80; H10K 59/122

(52) U.S. Cl. CPC H10K 59/80515; H10K 59/122

(57) ABSTRACT

A display device includes emission areas, a non-emission area surrounding the emission areas, anode electrodes spaced apart from each other, and separators respectively on the anode electrodes overlapping the non-emission area. Each of the anode electrodes overlaps each of the emission areas and the non-emission area.

### CROSS-REFERENCE TO RELATED APPLICATION

This application claims priority under 35 U.S.C. § 119 to Korean Patent Application No. 10-2024-0004183, filed on Jan. 10, 2024 in the Korean Intellectual Property Office, the disclosure of which is incorporated by reference herein in its entirety.

### TECHNICAL FIELD

The present disclosure relate to a display device and, more specifically, to a display device including separators on anode electrodes.

### DISCUSSION OF RELATED ART

As information technology develops, display devices are increasingly used as a means for communicating information to a user. Such display devices include a display panel such as a liquid crystal display (LCD) or an organic light emitting diode (OLED) display.

### SUMMARY

A display device includes emission areas, a non-emission area proximate to the emission areas, anode electrodes spaced apart from each other, and separators respectively disposed on the anode electrodes overlapping the non-emission area. Each of the anode electrodes overlaps each of the emission areas and the non-emission area.

Each of the separators may surround at least one surface of each of the emission areas.

Each of the separators may be proximate to three surfaces of each of the emission areas.

The display device may further include a pixel defining layer disposed on the anode electrodes and the separators and surrounding a remaining one surface of each of the emission areas, a light emitting structure disposed on the anode electrodes, the separators, and the pixel defining layer, and a cathode electrode disposed on the light emitting structure.

The separators may have a taper structure.

An angle of the taper structure, with respect to a plane of the anode electrodes, may be at least 50°.

A thickness of the taper structure may be greater than a thickness of the light emitting structure.

The separators may have an inverse taper structure that gets thicker farther away from the plurality of anode electrodes.

A thickness of the inverse taper structure may be greater than a thickness of the light emitting structure.

The light emitting structure and/or the cathode electrode may be split by the separators.

Each of the separators may surround four surfaces of each of the emission areas.

The display device may further include a pixel defining layer disposed on the anode electrodes and the separators and surrounding the separators, a light emitting structure disposed on the anode electrodes, the separators, and the pixel defining layer, and a cathode electrode disposed on the light emitting structure.

The separators may have a taper structure.

An angle of the taper structure, with respect to a plane of the plurality of anode electrodes, may be at least 50°.

A thickness of the taper structure may be greater than a thickness of the light emitting structure. The separators may have an inverse taper structure that gets thicker farther away from the plurality of anode electrodes.

A thickness of the inverse taper structure may be greater than a thickness of the light emitting structure.

The light emitting structure and/or the cathode electrode may be split by the separators.

The separators may include an inorganic material.

A display device includes an emission area. A non-emission area is proximate to the emission area. An anode electrode overlaps both the emission area and the non-emission area. A light-emitting structure is disposed on the anode electrode, within the emission area. A separator is disposed on the anode electrode and separates the emission area from the non-emission area. The separator has a shape that is wider farther from the anode electrode. The separator is disposed at a discontinuity of a cathode electrode and/or a light-emitting structure.

### BRIEF DESCRIPTION OF THE DRAWINGS

The above and other features of the present disclosure will become more apparent by describing in detail embodiments thereof with reference to the accompanying drawings, in which:

FIG. 1 is a block diagram illustrating a display device in accordance with an embodiment;

FIG. 2 is a block diagram illustrating any of sub-pixels of FIG. 1 in accordance with an embodiment;

FIG. 3 is a circuit diagram illustrating the sub-pixel of FIG. 2 in accordance with an embodiment;

FIG. 4 is a plan view illustrating a display panel of FIG. 1 in accordance with an embodiment;

FIG. 5 is an exploded perspective view illustrating a portion of the display panel of FIG. 4 in accordance with an embodiment;

FIG. 6 is a cross-sectional view illustrating a light emitting structure in accordance with an embodiment;

FIG. 7 is a cross-sectional view illustrating the light emitting structure in accordance with an embodiment;

FIG. 8 is a plan view illustrating a pixel in accordance with an embodiment;

FIG. 9 is a cross-sectional view taken along a line I-I′ of FIG. 8;

FIG. 10 is a cross-sectional view taken along the line I-I′ of FIG. 8;

FIG. 11 is a plan view illustrating an embodiment of the pixel;

FIG. 12 is a cross-sectional view taken along a line II-II′ of FIG. 11;

FIG. 13 is a block diagram illustrating a display system in accordance with an embodiment;

FIG. 14 is a perspective view illustrating an application example of the display system of FIG. 13; and

FIG. 15 is a diagram illustrating a head mounted display device worn by a user of FIG. 14.

### DETAILED DESCRIPTION OF THE EMBODIMENT

Hereinafter, various embodiments according to the disclosure are described in detail with reference to the accompanying drawings. It should be noted that in the following description, portions necessary for understanding an operation according to the disclosure are described, and descriptions of other portions may be omitted in order not to obscure the subject matter of the disclosure. In addition, the disclosure may be embodied in other forms without necessarily being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not necessarily intended to limit the disclosure. Throughout the specification, in a case where a certain portion “includes”, the case means that the portion may further include another component without excluding another component unless otherwise stated. “At least any of X, Y, and Z” and “at least any selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not necessarily limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein should not necessarily be construed as being limited to shown specific shapes, and should be interpreted as including, for example, changes in shapes that occur as a result of manufacturing. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, embodiments of the disclosure are described in detail with reference to the attached drawings.

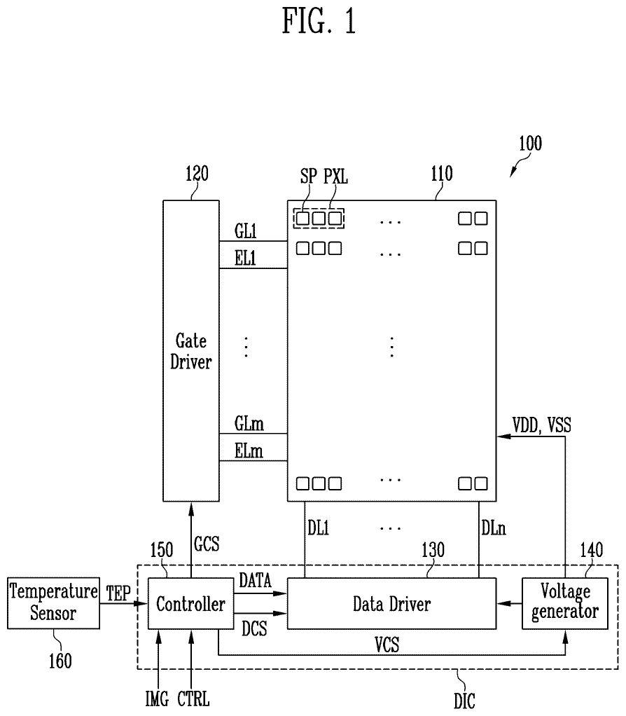

FIG. 1 is a block diagram illustrating a display device in accordance with an embodiment.

Referring to FIG. 1, the display device 100 may include a display panel 110, a gate driver 120, a data driver 130, a voltage generator 140, and a controller 150.

The display panel 110 includes sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels, among the sub-pixels SP, may configure one pixel PXL. For example, as shown in FIG. 1, three sub-pixels may configure one pixel PXL.

The gate driver 120 is electrically connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm electrically connected to the sub-pixels SP of the row direction may be further provided. In this case, the gate driver 120 may include an emission control driver configured to control the first to m-th emission control lines EL1 to ELm, and the emission control driver may operate under the control of the controller 150.

The gate driver 120 may be disposed on one side of the display panel 110. However, embodiments are not necessarily limited thereto. For example, the gate driver 120 may be divided into two or more physically and/or logically divided drivers, and such drivers may be disposed on one side of the display panel 110 and another side of the display panel 110 opposite the one side. As described above, the gate driver 120 may be disposed proximate to the display panel 110 and may have various shapes according to embodiments.

The data driver 130 is electrically connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DLI to DLn using voltages from the voltage generator 140. When the gate signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may generate the plurality of voltages by receiving an input voltage from an external source, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage may be applied to the first to n-th data lines DLI to DLn, and the voltage generator 140 may generate such a reference voltage.

The controller 150 controls overall operations of the display device 100. The controller 150 receives input image data IMG and a control signal CTRL for controlling display of the input image data IMG from an external source. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, the data driver 130, the voltage generator 140, and/or the controller 150 may be provided as a component distinguished from the driver integrated circuit DIC.

The display device 100 may include at least one temperature sensor 160. The temperature sensor 160 is configured to sense a temperature in its vicinity and generate temperature data TEP indicating the sensed temperature. In embodiments, the temperature sensor 160 may be disposed adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

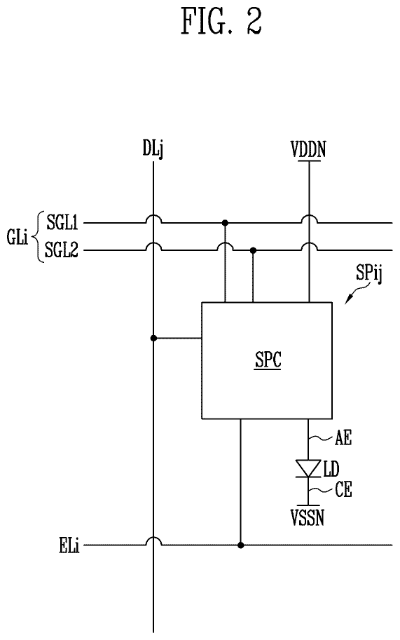

FIG. 2 is a block diagram illustrating any of sub-pixels of FIG. 1 in accordance with an embodiment. In FIG. 2, among the sub-pixels SP of FIG. 1, a sub-pixel SPij arranged in an i-th row (where i is an integer greater than or equal to 1 and less than or equal to m) and a j-th column (where j is an integer greater than or equal to 1 and less than or equal to n) is shown as an example.

Referring to FIG. 2, the sub-pixel SPij may include a sub-pixel circuit SPC and a light emitting element LD.

The light emitting element LD is electrically connected between a first power voltage node VDDN and a second power voltage node VSSN. At this time, the first power voltage node VDDN is a node that transfers the first power voltage VDD of FIG. 1, and the second power voltage node VSSN is a node that transfers the second power voltage VSS of FIG. 1.

An anode electrode AE of the light emitting element LD may be electrically connected to the first power voltage node VDDN through the sub-pixel circuit SPC, and a cathode electrode CE of the light emitting element LD may be electrically connected to the second power voltage node VSSN. For example, the anode electrode AE of the light emitting element LD may be electrically connected to the first power voltage node VDDN through one or more transistors included in the sub-pixel circuit SPC.

The sub-pixel circuit SPC may be electrically connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to the gate signals received through the first and/or second sub-gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

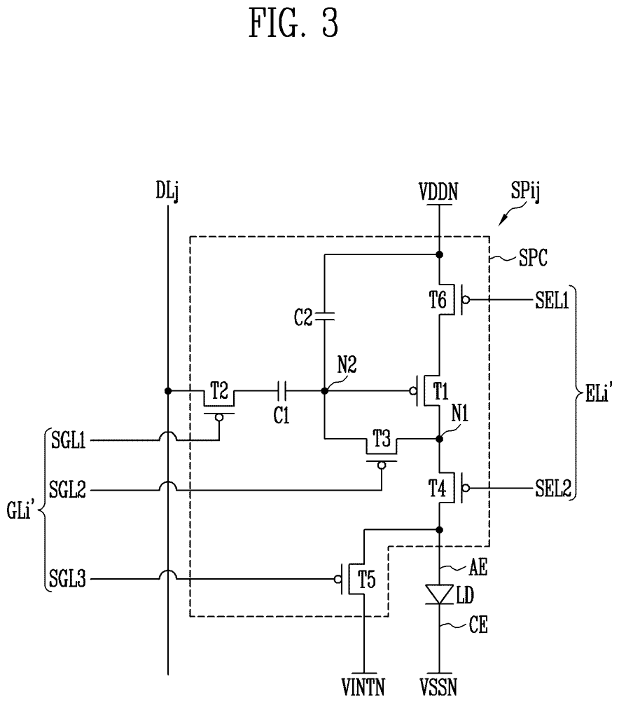

FIG. 3 is a circuit diagram illustrating the sub-pixel of FIG. 2 in accordance with an embodiment.

Referring to FIG. 3, the sub-pixel SPij may include a sub-pixel circuit SPC and a light emitting element LD.

The sub-pixel circuit SPC may be electrically connected to an i-th gate line GLi′, an i-th emission control line ELi′, and the j-th data line DLj. Compared to the i-th gate line GLi of FIG. 2, the i-th gate line GLi′ may further include a third sub-gate line SGL3. Compared to the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 is electrically connected between a first power voltage node VDDN and a first node N1. A gate of the first transistor T1 may be electrically connected to a second node N2, and thus the first transistor T1 may be turned on according to a voltage level of the second node N2. The first transistor T1 may be referred to as a driving transistor.

The second transistor T2 is electrically connected between the j-th data line DLj and the second node N2. A gate of the second transistor T2 may be electrically connected to the first sub-gate line SGL1, and thus the second transistor T2 may be turned on in response to a gate signal of the first sub-gate line SGL1. The second transistor T2 may be referred to as a switching transistor.

The third transistor T3 is electrically connected between the first node N1 and the second node N2. A gate of the third transistor T3 may be electrically connected to the second sub-gate line SGL2, and thus the third transistor T3 may be turned on in response to a gate signal of the second sub-gate line SGL2.

The fourth transistor T4 is electrically connected between the first node N1 and the anode electrode AE of the light emitting element LD. A gate of the fourth transistor T4 may be electrically connected to the second sub-emission control line SEL2, and thus the fourth transistor T4 may be turned on in response to an emission control signal of the second sub-emission control line SEL2.

The fifth transistor T5 is electrically connected between the anode electrode AE of the light emitting element LD and an initialization voltage node VINTN. The initialization voltage node VINTN is configured to transfer an initialization voltage. In embodiments, the initialization voltage may be provided by voltage generator 140 of FIG. 1. In other embodiments, the initialization voltage may be provided by an external device of the display device 100. A gate of the fifth transistor T5 may be electrically connected to the third sub-gate line SGL3, and thus the fifth transistor T5 may be turned on in response to a gate signal of the third sub-gate line SGL3.

The sixth transistor T6 is electrically connected between the first power voltage node VDDN and the first transistor T1. A gate of the sixth transistor T6 may be electrically connected to the first sub-emission control line SEL1, and thus the sixth transistor T6 may be turned on in response to an emission control signal of the first sub-emission control line SEL1.

The first capacitor C1 is electrically connected between the second transistor T2 and the second node N2. The second capacitor C2 is electrically connected between the first power voltage node VDDN and the second node N2.

As described above, the sub-pixel circuit SPC may include the first to sixth transistors T1 to T6, and the first and second capacitors C1 and C2. However, embodiments are not necessarily limited thereto. The sub-pixel circuit SPC may be implemented as any of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be variable.

The first to sixth transistors T1 to T6 may be P-type transistors. Each of the first to sixth transistors T1 to T6 may be a metal oxide silicon field effect transistor (MOSFET). However, embodiments are not necessarily limited thereto. For example, at least one of the first to sixth transistors T1 to T6 may be replaced with an N-type transistor.

In embodiments, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, the cathode electrode CE, and the light emitting layer. The light emitting layer may be disposed between the anode electrode AE and the cathode electrode CE. After the data signal transferred through the j-th data line DLj is reflected in a voltage of the second node N2, when the emission control signals of the first and second sub-emission control lines SEL1 and SEL2 are enabled to a low level, the fourth and sixth transistors T4 and T6 may be turned on. In addition, the first transistor T1 may be turned on according to the voltage of the second node N2, and thus a current may flow from the first power voltage node VDDN to the second power voltage node VSSN. The light emitting element LD may emit light according to an amount of the flowing current.

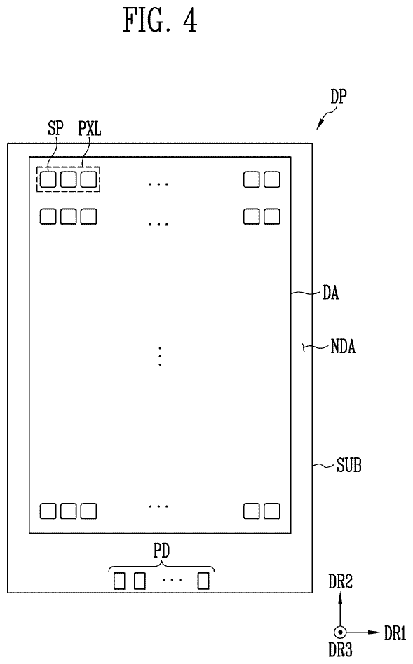

FIG. 4 is a plan view illustrating a display panel of FIG. 1 in accordance with an embodiment.

Referring to FIG. 4, an embodiment DP of the display panel 110 of FIG. 1 may include a display area DA and a non-display area NDA. The display panel DP displays an image through the display area DA. The non-display area NDA is disposed proximate to the display area DA.

The display panel DP may include a substrate SUB, the sub-pixels SP, and pads PD.

When the display panel DP is used as a display screen of a head mounted display (HMD), a virtual reality (VR) device, a mixed reality (MR) device, an augmented reality (AR) device, or the like, the display panel DP may be positioned very close to user's eyes. In this case, sub-pixels SP of a relatively high integration degree are needed. To increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP are disposed in the display area DA on the substrate SUB. The sub-pixels SP may be arranged in a matrix shape along a first direction DR1 and a second direction DR2 crossing the first direction DR1. However, embodiments are not necessarily limited thereto. For example, the sub-pixels SP may be arranged in a zigzag shape along the first direction DR1 and the second direction DR2. For example, the sub-pixels SP may be arranged in a PENTILE™ shape, where PENTILE™ is an arrangement of luminous areas manufactured by SAMSUNG. The first direction DR1 may be a row direction, and the second direction DR2 may be a column direction.

Two or more sub-pixels among the plurality of sub-pixels SP may configure one pixel PXL.

A component for controlling the sub-pixels SP may be disposed in the non-display area NDA on the substrate SUB. For example, lines electrically connected to the sub-pixels SP, such as the first to m-th gate lines GL1 to GLm and the first to n-th data lines DLI to DLn of FIG. 1, may be disposed in the non-display area NDA.

The gate driver 120, the data driver 130, the voltage generator 140, the controller 150, and/or the temperature sensor 160 of FIG. 1 may be integrated in the non-display area NDA of the display panel DP. In embodiments, the gate driver 120 of FIG. 1 may be mounted on the display panel DP and may be disposed in the non-display area NDA. In other embodiments, the gate driver 120 may be implemented as an integrated circuit separated from the display panel DP. In embodiments, the temperature sensor 160 may be disposed in the non-display area NDA to sense a temperature of the display panel DP.

The pads PD are disposed in the non-display area NDA on the substrate SUB. The pads PD may be electrically connected to the sub-pixels SP through lines. For example, the pads PD may be electrically connected to the sub-pixels SP through the first to n-th data lines DL1 to DLn.

The pads PD may interface the display panel DP to other components of the display device 100 (refer to FIG. 1). In embodiments, voltages and signals necessary for an operation of components included in the display panel DP may be provided from the driver integrated circuit DIC of FIG. 1 through the pads PD. For example, the first to n-th data lines DL1 to DLn may be electrically connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member such as an anisotropic conductive film. At this time, the circuit board may be a flexible circuit board (FPCB) or a flexible film having a flexible material. The driver integrated circuit DIC may be mounted on the circuit board and may be electrically connected to the pads PD.

In embodiments, the display area DA may have various shapes. The display area DA may have a closed loop shape including straight and/or curved sides. For example, the display area DA may have shapes such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable to at least an extent that is noticeable, without cracking or otherwise sustaining damage. In these cases, the display panel DP and/or the substrate SUB may include materials having a flexible property.

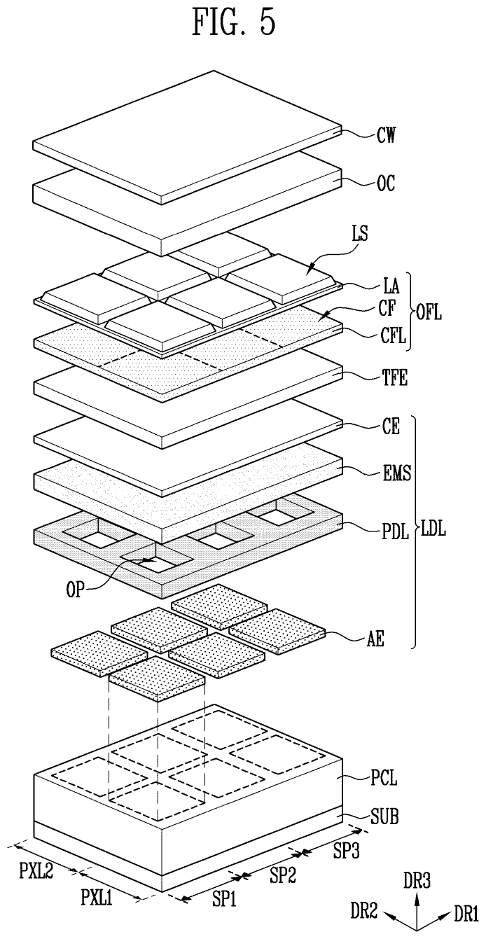

FIG. 5 is an exploded perspective view illustrating a portion of the display panel of FIG. 4 in accordance with an embodiment. In FIG. 5, for clear and concise description, a portion of the display panel DP corresponding to two pixels PXL1 and PXL2 among the pixels PXL of FIG. 4 is schematically shown. A portion of the display panel DP corresponding to remaining pixels may be similarly configured.

Referring to FIGS. 4 and 5, each of the first and second pixels PXL1 and PXL2 may include first to third sub-pixels SP1 to SP3. However, embodiments are not necessarily limited thereto. For example, each of the first and second pixels PXL1 and PXL2 may include four sub-pixels or two sub-pixels.

In FIG. 5, the first to third sub-pixels SP1 to SP3 have quadrilateral shapes when viewed from a third direction DR3 crossing the first and second directions DR1 and DR2, and have sizes equal to each other. However, embodiments are not necessarily limited thereto. The first to third sub-pixels SP1 to SP3 may be modified to have various shapes.

The display panel DP may include the substrate SUB, a pixel circuit layer PCL, a light emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL is disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like. The conductive patterns may include copper (Cu), but embodiments are not necessarily limited thereto.

The circuit elements may include the sub-pixel circuit SPC (refer to FIG. 2) for each of the first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines electrically connected to each of the first to third sub-pixels SP1 to SP3, for example, a gate line, an emission control line, a data line, and the like. The lines may further include a line electrically connected to the first power voltage node VDDN of FIG. 2. In addition, the lines may further include a line electrically connected to the second power voltage node VSSN of FIG. 2.

The light emitting element layer LDL may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but embodiments are not necessarily limited thereto.

The pixel defining layer PDL is disposed on the anode electrodes AE. The pixel defining layer PDL may include an opening OP exposing a portion of each of the anode electrodes AE. The opening OP of the pixel defining layer PDL may be understood to be emission areas corresponding to the first to third sub-pixels SP1 to SP3, respectively.

In embodiments, the pixel defining layer PDL may include an inorganic material. In this case, the pixel defining layer PDL may include a plurality of stacked inorganic layers. For example, the pixel defining layer PDL may include silicon oxide SiOx and silicon nitride SiNx. In other embodiments, the pixel defining layer PDL may include an organic material. However, a material of the pixel defining layer PDL is not necessarily limited thereto.

The light emitting structure EMS may be disposed on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and the like.

In embodiments, the light emitting structure EMS may fill the opening OP of the pixel defining layer PDL, and may be entirely disposed on the pixel defining layer PDL. For example, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments are not necessarily limited thereto. For example, portions of the light emitting structure EMS corresponding to the first to third sub-pixels SP1 to SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively small thickness. In embodiments, the cathode electrode CE may include various transparent conductive materials including indium tin oxide, indium zinc oxide, indium tin zinc oxide, aluminum zinc oxide, gallium zinc oxide, zinc tin oxide, and/or gallium tin oxide. In other embodiments, the cathode electrode CE may include silver (Ag), magnesium (Mg), or a mixture thereof. However, a material of the cathode electrode CE is not necessarily limited thereto.

It may be understood that any of the anode electrodes AE, a portion of the light emitting structure EMS overlapping it, and a portion of the cathode electrode CE overlapping it configure one light emitting element LD (refer to FIG. 2). For example, each of the light emitting elements of the first to third sub-pixels SP1 to SP3 may include one anode electrode, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to combine and form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is disposed on the cathode electrode CE. The encapsulation layer TFE may cover the light emitting element layer LDL and/or the pixel circuit layer PCL. The encapsulation layer TFE may prevent oxygen, moisture, and/or the like from permeating to the light emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulation layer TFE are not necessarily limited thereto.

To increase an encapsulation efficiency of the encapsulation layer TFE, the encapsulation layer TFE may further include a thin film including aluminum oxide (AlOx). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments are not necessarily limited thereto. The encapsulation layer TFE may further include a thin film formed of various materials suitable for increasing the encapsulation efficiency.

The optical functional layer OFL is disposed on the encapsulation layer TFE. The optical functional layer OFL may include a color filter layer CFL and a lens array LA.

The color filter layer CFL is disposed between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA is disposed on the color filter layer CFL. The lens array LA may include lenses LS respectively corresponding to the first to third sub-pixels SP1 to SP3. Each of the lenses LS may increase light output efficiency by outputting the light emitted from the light emitting structure EMS to an intended path. The lens array LA may have a relatively high refractive index. For example, the lens array LA may have a refractive index that is higher than that of the overcoat layer OC. In embodiments, the lenses LS may include an organic material. In embodiments, the lenses LS may include an acrylic material. However, a material of the lenses LS is not necessarily limited thereto.

In embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA, a center of the color filter and a center of the lens may be aligned with or overlap with a center of the opening OP of the corresponding pixel definition layer PDL when viewed in the third direction DR3. For example, in the central area of the display area DA, the opening OP of the pixel defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the opening OP of the corresponding pixel defining layer PDL when viewed in the third direction DR3. For example, in the area adjacent to the non-display area NDA in the display area DA, the opening OP of the pixel defining layer PDL may partially overlap the corresponding color filter of the color filter layer CFL and the corresponding lens of the lens array LA. Accordingly, at a center of the display area DA, the light emitted from the light emitting structure EMS may be efficiently output in a normal direction of a display surface. At an outer region of the display area DA, the light emitted from the light emitting structure EMS may be efficiently output in a direction inclined by a predetermined angle with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include an inorganic insulating layer and/or an organic insulating layer. For example, the overcoat layer OC may include epoxy, but embodiments are not necessarily limited thereto. The overcoat layer OC may have a refractive index that is lower than that of the lens array LA.

The cover window CW may be disposed on the overcoat layer OC. The cover window CW is configured to protect layers thereunder. The cover window CW may have a refractive index that is higher than that of the overcoat layer OC. The cover window CW may include glass, but embodiments are not necessarily limited thereto. For example, the cover window CW may be an encapsulation glass configured to protect components disposed thereunder. In other embodiments, the cover window CW may be omitted.

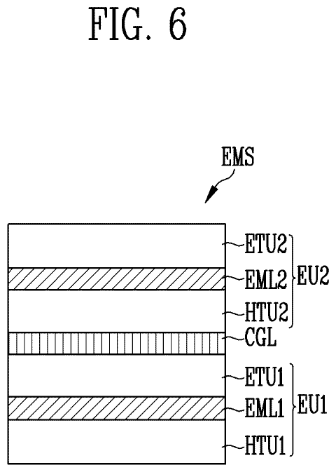

FIG. 6 is a cross-sectional view illustrating a light emitting structure in accordance with an embodiment.

Referring to FIG. 6, the light emitting structure EMS may have a tandem structure in which first and second light emitting units EU1 and EU2 are stacked.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include a hole injection layer and/or a hole transport layer, and may further include a hole buffer layer, an electron blocking layer, and the like, if necessary. The first and second hole transport units HTU1 and HTU2 may have the same or different configurations from each other.

Each of the first and second electron transport units ETU1 and ETU2 may include an electron injection layer and/or an electron transport layer, and may further include an electron buffer layer, a hole blocking layer, and the like, if necessary. The first and second electron transport units ETU1 and ETU2 may have the same or different configurations from each other.

A connection layer, which may be provided in a form of a charge generation layer CGL, may be disposed between the first light emitting unit EU1 and the second light emitting unit EU2 to connect the first light emitting unit EU1 and the second light emitting unit EU2 to each other. In embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments are not necessarily limited thereto.

In embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate light of a blue color, and the second light emitting layer EML2 may generate light of a yellow color. In embodiments, the second light emitting layer EML2 may include a structure in which a first sub light emitting layer configured to generate light of a red color and a second sub light emitting layer configured to generate light of a green color are stacked. The light of the red color and the light of the green color may be mixed, and thus the light of the yellow color may be provided. In this case, an intermediate layer configured to perform a function of transporting holes and/or blocking transport of electrons may be further disposed between the first and second sub light emitting layers.

In other embodiments, the first light emitting layer EML1 and the second light emitting layer EML2 may generate light of the same color.

In embodiments, the light emitting structure EMS may be formed through a method of vacuum deposition, inkjet printing, or the like, but embodiments are not necessarily limited thereto.

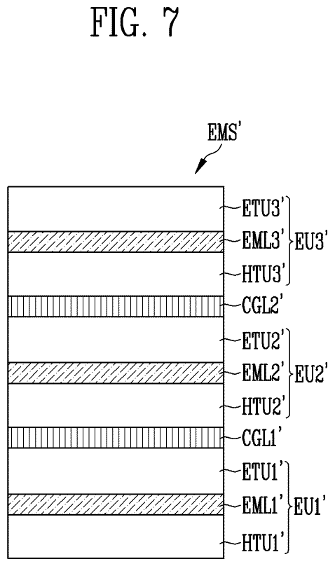

FIG. 7 is a cross-sectional view illustrating the light emitting structure in accordance with an embodiment.

Referring to FIG. 7, the light emitting structure EMS′ may have a tandem structure in which first to third light emitting units EU1′ to EU3′ are stacked.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include a hole injection layer and/or a hole transport layer, and may further include a hole buffer layer, an electron blocking layer, and the like if necessary. The first to third hole transport units HTU1′ to HTU3′ may have the same or different configurations from each other.

Each of the first to third electron transport units ETU1′ to ETU3′ may include an electron injection layer and/or an electron transport layer, and may further include an electron buffer layer, a hole blocking layer, and the like, if necessary. The first to third electron transport units ETU1′ to ETU3′ may have the same or different configurations from each other.

A first charge generation layer CGL1′ is disposed between the first light emitting unit EU1′ and the second light emitting unit EU2′. A second charge generation layer CGL2′ is disposed between the second light emitting unit EU2′ and the third light emitting unit EU3′.

In embodiments, the first to third light emitting layers EML1′ to EML3′ may generate light of different colors. Light emitted from each of the first to third light emitting layers EML1′ to EML3′ may be mixed and may be viewed as white light. For example, the first emitting layer EML1′ may generate light of a blue color, the second emitting layer EML2′ may generate light of a green color, and the third emitting layer EML3′ may generate light of a red color.

In other embodiments, two or more light emitting layers among the first to third light emitting layers EML1′ to EML3′ may generate light of the same color.

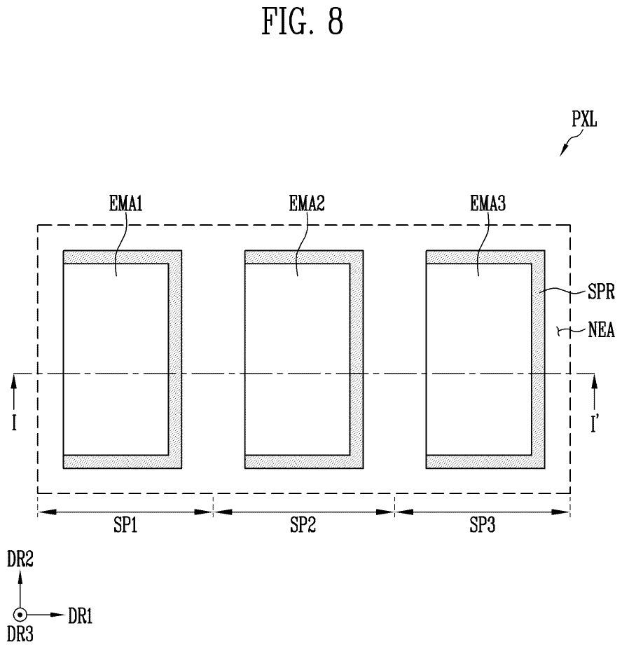

FIG. 8 is a plan view illustrating a pixel in accordance with an embodiment.

Referring to FIG. 8, the pixel PXL may include the first to third sub-pixels SP1 to SP3 arranged in the first direction DR1.

The first sub-pixel SP1 may include a first emission area EMA1 and a non-emission area NEA proximate to the first emission area EMA1. The second sub-pixel SP2 may include a second emission area EMA2 and a non-emission area NEA proximate to the second emission area EMA2. The third sub-pixel SP3 may include a third emission area EMA3 and a non-emission area NEA proximate to the third emission area EMA3.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3.

The pixel PXL may include separators SPR surrounding the respective first to third emission areas EMA1 to EMA3. The separators SPR may overlap the non-emission area NEA.

The separators SPR may surround at least one surface of each of the first to third emission areas EMA1 to EMA3. As used herein, the phrase “surround at least on surface” means that the first element is proximate to the second element at one or more surface thereof. For example, any of the separators SPR may surround three surfaces of the first emission area EMA1. Another one of the separators SPR may surround three surfaces of the second emission area EMA2. Still another one of the separators SPR may surround three surfaces of the third emission area MEA3. In this case, one surface among four surfaces of the first to third emission areas EMA1 to EMA3 may be exposed. Differently from FIG. 8, three surfaces of the first to third emission areas EMA1 to EMA3 surrounded by each of the separators SPR may be changed. Similarly, an exposed first surface of the first to third emission areas EMA1 to EMA3 may also be changed.

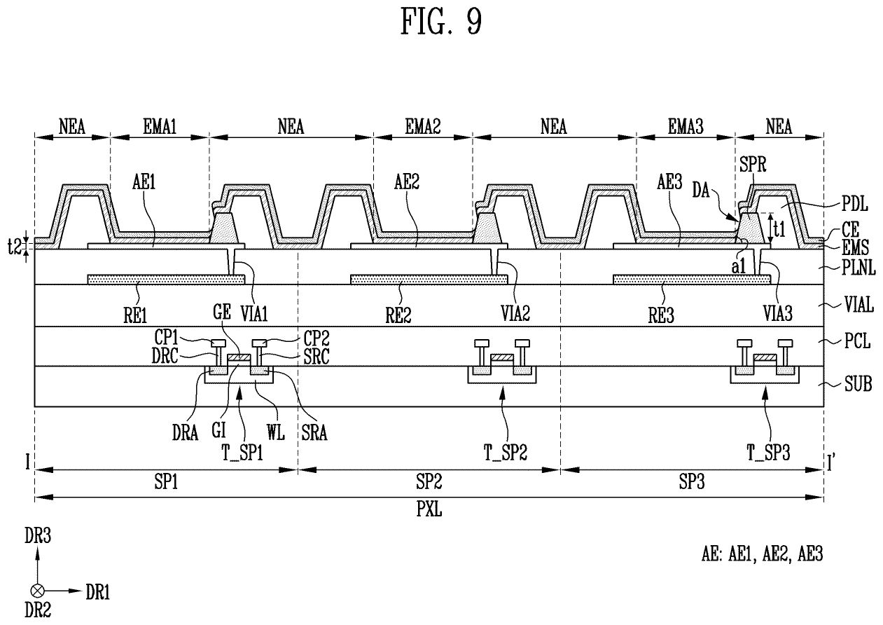

FIG. 9 is a cross-sectional view taken along a line I-I′ of FIG. 8.

Referring to FIG. 9, the substrate SUB and the pixel circuit layer PCL disposed on the substrate SUB are provided.

The substrate SUB may include a silicon wafer substrate formed using a semiconductor process. For example, the substrate SUB may include silicon, germanium, and/or silicon-germanium.

The pixel circuit layer PCL is disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any of the transistors included in the sub-pixel circuit SPC (refer to FIG. 2) of the first sub-pixel SP1, the transistor T_SP2 of the second sub-pixel SP2 may be any of the transistors included in the sub-pixel circuit SPC of the second sub-pixel SP2, and the transistor T_SP3 of the third sub-pixel SP3 may be any of the transistors included in the sub-pixel circuit SPC of the third sub-pixel SP3. In FIG. 7, for clear and concise description, one of the transistors of each sub-pixel is shown, and the remaining circuit elements are omitted. To the extent that an element is not described in detail with respect to this figure, it may be understood that the element is at least similar to a corresponding element that has been described elsewhere within the present disclosure.

The transistor T_SP1 of the first sub-pixel SP1 may include a source area SRA, a drain area DRA, and a gate electrode GE.

The source area SRA and drain area DRA may be disposed in the substrate SUB. A well WL formed through an ion injection process may be disposed in the substrate SUB, and the source area SRA and the drain area DRA may be spaced apart from each other in the well WL. An area between the source area SRA and the drain area DRA in the well WL may be defined as a channel area.

The gate electrode GE may overlap the channel area between the source area SRA and the drain area DRA and may be disposed in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns disposed between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are electrically connected to different circuit elements and/or lines, the transistor T_SP1 of the first sub-pixel SP1 may be provided as any of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL is disposed on the pixel circuit layer PCL. The via layer VIAL may cover the pixel circuit layer PCL and may have an overall flat surface. The via layer VIAL is configured to planarize steps on the pixel circuit layer PCL. The via layer VIAL may include silicon oxide (SiOx), silicon nitride (SiNx), and/or silicon carbon nitride (SiCN), but embodiments are not necessarily limited thereto.

The light emitting element layer LDL is disposed on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are disposed in the first to third sub-pixels SP1 to SP3, respectively. Each of the first to third reflective electrodes RE1 to RE3 may contact the circuit element disposed in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from them, but embodiments are not necessarily limited thereto.

In embodiments, a connection electrode may be disposed under each of the first to third reflective electrodes RE1 to RE3. The connection electrode may increase an electrical connection between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments are not necessarily limited thereto. In embodiments, a corresponding reflective electrode may be positioned between multiple layers of the connection electrode.

The first to third reflective electrodes RE1 to RE3 may function as full mirrors (e.g., mirrors capable of full reflection), and the cathode electrode CE may function as a half mirror (e.g., mirror capable of half reflection and half transmission). The light emitted from the light emitting layer of the light emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood to be a resonance distance for the light emitted from the light emitting layer of the corresponding light emitting structure EMS.

To planarize steps between the first to third reflective electrodes RE1 to RE3, a planarization layer PLNL may be disposed on the via layer VIAL and the first to third reflective electrodes RE1 to RE3. The planarization layer PLNL may generally cover the first to third reflective electrodes RE1 to RE3 and the via layer VIAL, and may have a flat surface. In embodiments, the planarization layer PLNL may be omitted.

On the planarization layer PLNL, the first to third anode electrodes AE1 to AE3 respectively overlapping the first to third reflective electrodes RE1 to RE3 are disposed. The first to third anode electrodes AE1 to AE3 may have shapes similar to those of the first to third emission areas EMA1 to EMA3 of FIG. 8 when viewed in the third direction DR3. The first to third anode electrodes AE1 to AE3 are respectively electrically connected to the first to third reflective electrodes RE1 to RE3. The first anode electrode AE1 may be electrically connected to the first reflective electrode RE1 through a first via VIA1 passing through the planarization layer PLNL. The second anode electrode AE2 may be electrically connected to the second reflective electrode RE2 through a second via VIA2 passing through the planarization layer PLNL. The third anode electrode AE3 may be electrically connected to the third reflective electrode RE3 through a third via VIA3 passing through the planarization layer PLNL.

In embodiments, the first to third anode electrodes AE1 to AE3 may include transparent conductive materials such as indium tin oxide (ITO), indium zinc oxide (IZO), zinc oxide (ZnOₓ), indium gallium zinc oxide (IGZO), and/or indium tin zinc oxide (ITZO). However, a material of the first to third anode electrodes AE1 to AE3 is not necessarily limited thereto. For example, the first to third anode electrodes AE1 to AE3 may include titanium nitride.

The separators SPR may be disposed on the anode electrodes AE. The respective separators SPR may be disposed on the respective anode electrodes AE overlapping the non-emission area NEA. For example, any of the separators SPR may be disposed on the first anode electrode AE1 overlapping the non-emission area NEA. Another one of the separators SPR may be disposed on the second anode electrode AE2 overlapping the non-emission area NEA. Still another one of the separators SPR may be disposed on the third anode electrode AE3 overlapping the non-emission area NEA. For example, the separators SPR may be disposed so as not to overlap the first to third emission areas EMA1 to EMA3 and might not affect the light emission area. In addition, the separators SPR may be easily formed on the anode electrodes AE in a desired shape without an effect of a lower structure. For example, the separators SPR may be formed by chemical vapor deposition (CVD), but embodiments are not necessarily limited thereto.

As described above, the respective separators SPR may be disposed on the anode electrodes AE to surround three surfaces of each of the first to third emission areas EMA1 to EMA3. In the I-I′ cross-section, one separator SPR may be disposed on each of the anode electrodes AE.

In an embodiment, the separators SPR may include an inorganic material. For example, the separators SPR may include an inorganic material such as SiNx, SiOx, or SiON, but embodiments are not necessarily limited thereto.

In an embodiment, the separators SPR may have a taper structure. The separators SPR having the taper structure may cause formation of a discontinuous area DA in which the light emitting structure EMS and/or the cathode electrode CE is disconnected or bent. A taper angle al of the separators SPR having the taper structure may be at least 50° with respect to a surface from which it extends. A thickness t1 of the separators SPR having the taper structure may be greater than a thickness t2 of the light emitting structure EMS. When a standard of the separators SPR having the taper structure accords with the above-described condition, the above-described discontinuous area DA may be effectively formed.

The pixel defining layer PDL may be disposed on portions of the separators SPR and the anode electrodes AE. In addition, the pixel defining layer PDL may be disposed on the planarization layer PLNL. The pixel defining layer PDL may overlap the non-emission area NEA.

The pixel defining layer PDL may define the first to third emission areas EMA1 to EMA3 overlapping the respective first to third anode electrodes AE1 to AE3 together with the separators SPR. In cross-section, the pixel defining layer PDL may surround the separators SPR. In addition, the pixel defining layer PDL may surround one surface, which is not surrounded by the separators SPR, among the four surfaces of each of the first to third emission areas EMA1 to EMA3 shown in FIG. 8.

The pixel defining layer PDL may include a plurality of inorganic insulating layers. Each of the plurality of inorganic insulating layers may include silicon oxide SiOx and/or silicon nitride SiNx. For example, the pixel defining layer PDL may include first to third inorganic insulating layers sequentially stacked, and the first to third inorganic insulating layers may include silicon nitride, silicon oxide, and silicon nitride, respectively, but embodiments are not necessarily limited thereto.

The light emitting structure EMS may be disposed on the anode electrodes AE exposed by the pixel defining layer PDL and the separators SPR. Although not shown in FIG. 9, the light emitting structure EMS may be disposed on the anode electrodes AE exposed by the respective separators SPR. The light emitting structure EMS may be disposed entirely across the first to third sub-pixels SP1 to SP3. For example, the light emitting structure EMS may extend along the pixel defining layer PDL and may be disposed on the planarization layer PLNL.

The light emitting structure EMS may be disconnected or bent on the separators SPR. For example, the charge generation layer CGL (refer to FIG. 6) included in the light emitting structure EMS may be disconnected or bent in the discontinuous area DA caused by the separators SPR. Accordingly, when the display panel DP (refer to FIG. 4) is operated, a current flowing from each of the first to third sub-pixels SP1 to SP3 to a sub-pixel adjacent thereto through the charge generation layer CGL may be reduced.

The cathode electrode CE may be disposed on the light emitting structure EMS. The cathode electrode CE may be commonly provided to the first to third sub-pixels SP1 to SP3. The cathode electrode CE may function as a half mirror that partially transmits and partially reflects light emitted from the light emitting structure EMS. According to an embodiment, the cathode electrode CE may be disconnected or bent on the separators SPR. For example, the cathode electrode CE may be disconnected or bent in the discontinuous area DA caused by the separators SPR.

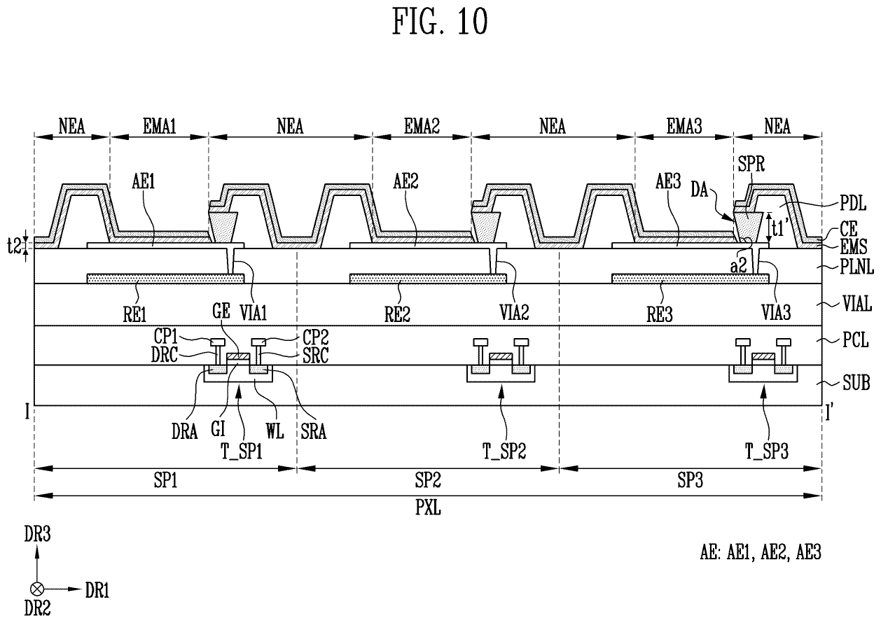

FIG. 10 is another cross-sectional view taken along the line I-I′ of FIG. 8. In relation to FIG. 10, a description of a content overlapping that of FIG. 9 is simplified or omitted. To the extent that an element is not described in detail with respect to this figure, it may be understood that the element is at least similar to a corresponding element that has been described elsewhere within the present disclosure.

Referring to FIG. 10, in an embodiment, the separators SPR may have an inverse taper structure. The separators SPR having the inverse taper structure may cause the formation of the discontinuous area DA in which the light emitting structure EMS and/or the cathode electrode CE is disconnected or bent. An inverse taper angle a2 of the separators SPR having the inverse taper structure may be greater than 90°. A thickness t1′ of the separators SPR having the inverse taper structure may be greater than the thickness t2 of the light emitting structure EMS. The thickness t1′ of the separators SPR having the inverse taper structure may be equal to or different from the thickness t1 of the separators SPR (refer to FIG. 9) having the taper structure. When a standard of the separators SPR having the inverse taper structure accord with the above-described condition, the above-described discontinuous area DA may be effectively formed.

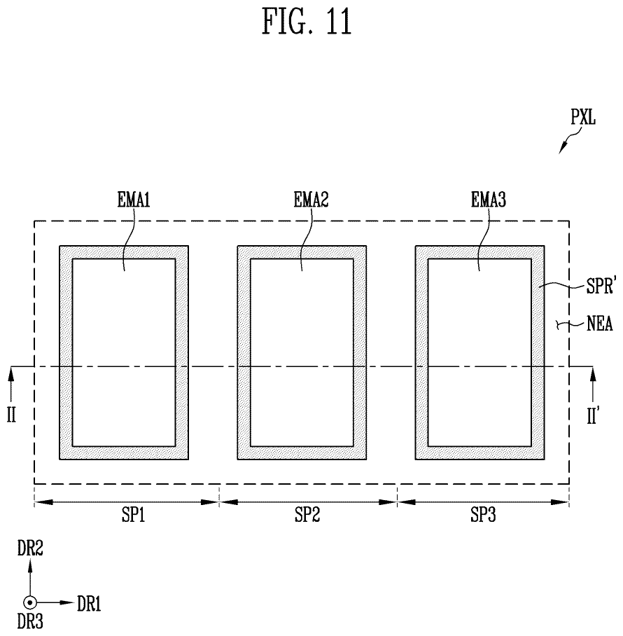

FIG. 11 is a plan view illustrating another embodiment of the pixel. In relation to FIG. 11, a description of a content overlapping that of FIG. 8 is simplified or omitted. To the extent that an element is not described in detail with respect to this figure, it may be understood that the element is at least similar to a corresponding element that has been described elsewhere within the present disclosure.

Referring to FIG. 11, the pixel PXL may include separators SPR′ surrounding the respective first to third emission areas EMA1 to EMA3. The separators SPR′ may overlap the non-emission area NEA.

In an embodiment, each of the separators SPR′ may surround four surfaces (or the entire surface) of each of the first to third emission areas EMA1 to EMA3. For example, any of the separators SPR′ may surround the four surfaces of the first emission area EMA1. Another one of the separators SPR′ may surround the four surfaces of the second emission area EMA2. Still another one of the separators SPR′ may surround the four surfaces of the third emission area EMA3. In this case, the four surfaces of the first to third emission areas EMA1 to EMA3 may be completely surrounded by the separators SPR′ and might not be exposed.

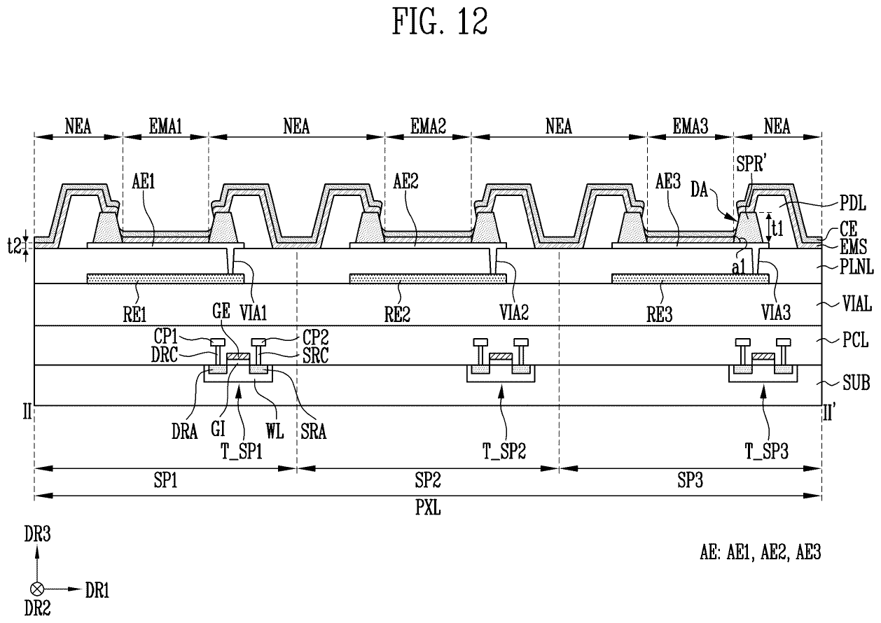

FIG. 12 is a cross-sectional view taken along a line II-II′ of FIG. 11. In relation to FIG. 12, a description of a content overlapping that of FIG. 9 is simplified or omitted. To the extent that an element is not described in detail with respect to this figure, it may be understood that the element is at least similar to a corresponding element that has been described elsewhere within the present disclosure.

Referring to FIG. 12, the separators SPR′ may be disposed on the anode electrodes AE. The respective separators SPR′ may be disposed on the respective anode electrodes AE overlapping the non-emission area NEA. For example, any of the separators SPR′ may be disposed on the first anode electrode AE1 overlapping the non-emission area NEA. Another one of the separators SPR′ may be disposed on the second anode electrode AE2 overlapping the non-emission area NEA. Still another one of the separators SPR′ may be disposed on the third anode electrode AE3 overlapping the non-emission area NEA. For example, the separators SPR′ may be disposed so as not to overlap the first to third emission areas EMA1 to EMA3 and might not affect the light emitting area. In addition, the separators SPR′ may be easily formed on the anode electrodes AE in a desired shape without an effect of a lower structure. For example, the separators SPR′ may be formed by chemical vapor deposition (CVD), but embodiments are not necessarily limited thereto.

As described above, the respective separators SPR′ may be disposed on the anode electrodes AE to surround the four surfaces of each of the first to third emission areas EMA1 to EMA3. In the II-II′ cross section, two separators SPR′ may be disposed on each of the anode electrodes AE.

In an embodiment, the separators SPR′ may include an inorganic material. For example, the separators SPR′ may include an inorganic material such as SiNx, SiOx, or SiON, but embodiments are not necessarily limited thereto.

In an embodiment, the separators SPR′ may have a taper structure. The separators SPR′ having the taper structure may cause the formation of the discontinuous area DA in which the light emitting structure EMS and/or the cathode electrode CE is disconnected or bent. The taper angle al of the separators SPR′ having the taper structure may be at least 50°. The thickness t1 of the separators SPR′ having the taper structure may be greater than the thickness t2 of the light emitting structure EMS. When a standard of the separators SPR′ having the taper structure accords with the above-described condition, the above-described discontinuous area DA may be effectively formed. The separators SPR′ may have the inverse taper structure as shown in FIG. 10.

The pixel defining layer PDL may be disposed on portions of the separators SPR′ and the anode electrodes AE. In addition, the pixel defining layer PDL may be disposed on the planarization layer PLNL. The pixel defining layer PDL may overlap the non-emission area NEA. In cross-section, the pixel defining layer PDL may completely surround the separators SPR′.

The light emitting structure EMS may be disposed on the anode electrodes AE exposed by the respective separators SPR′. In addition, the light emitting structure EMS may be disposed on the separators SPR′, may extend along the pixel defining layer PDL, and may be disposed on the planarization layer PLNL.

The light emitting structure EMS may disconnected or bend on the separators SPR′. For example, the charge generation layer CGL (refer to FIG. 6) included in the light emitting structure EMS may be disconnected or bent in the discontinuous area DA caused by the separators SPR′. Accordingly, when the display panel DP (refer to FIG. 4) is operated, the current flowing from each of the first to third sub-pixels SP1 to SP3 to the sub-pixel adjacent thereto through the charge generation layer CGL may be reduced. In particular, since the separators SPR′ are disposed to surround the four surfaces of each of the first to third emission areas EMA1 to EMA3, a possibility of a current leakage to an adjacent sub-pixel may be further reduced.

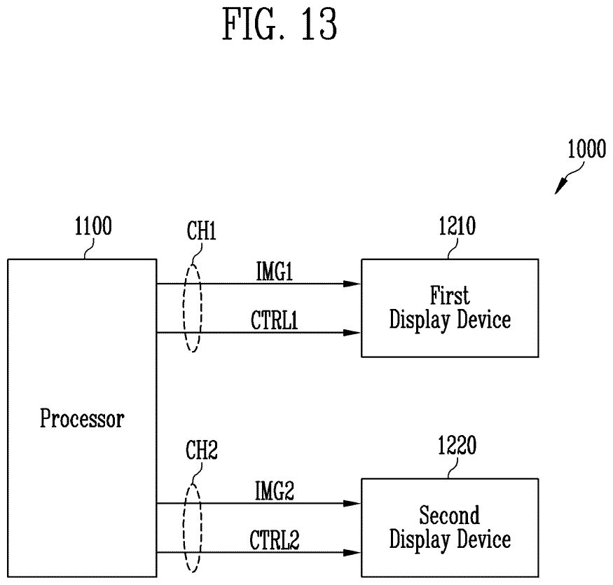

FIG. 13 is a block diagram illustrating a display system in accordance with an embodiment.

Referring to FIG. 13, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control the other components.

In FIG. 13, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra mobile personal computer (UMPC). In addition, the display system 1000 may include a head mounted display (HMD) device, a virtual reality (VR) device, a mixed reality (MR) device, and/or an augmented reality (AR) device.

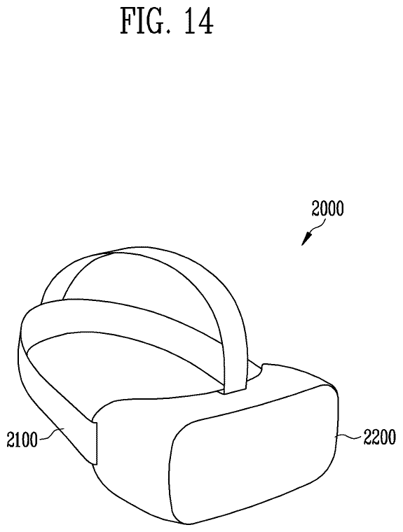

FIG. 14 is a perspective view illustrating an application example of the display system of FIG. 13.

Referring to FIG. 14, the display system 1000 of FIG. 13 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may surround a side portion of the user's head, and the vertical band may surround an upper portion of the user's head. However, embodiments are not necessarily limited thereto. For example, the head mount band 2100 may be implemented in a glasses frame form, a helmet form, or the like.

The display device receiving case 2200 may receive the first and second display devices 1210 and 1220 of FIG. 13. The display device receiving case 2200 may further receive the processor 1100 of FIG. 13.

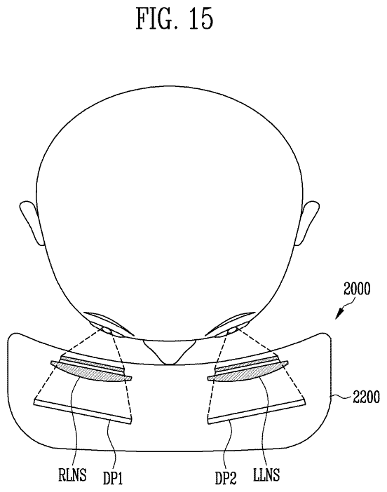

FIG. 15 is a diagram illustrating the head mounted display device worn by a user of FIG. 14.

Referring to FIG. 15, in a head mounted display device 2000, a first display panel DP1 of the first display device 1210 and a second display panel DP2 of the second display device 1220 are disposed. The head mounted display device 2000 may further include one or more lenses LLNS and RLNS.

Within the display device receiving case 2200, the right eye lens RLNS may be disposed between the first display panel DP1 and a user's right eye. Within the display device receiving case 2200, the left eye lens LLNS may be disposed between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Although specific embodiments and application examples are described herein, other embodiments and modifications may be derived from the above description. Therefore, the spirit of the disclosure is not necessarily limited to such embodiments, and extends to the scope of the claims set forth below, various obvious modifications, and equivalents.

Although the disclosure has been specifically described according to the above-described embodiments, it should be noted that the above-described embodiments are for describing the disclosure and not necessarily for limiting the scope of the disclosure. Those of ordinary skill in the art to which the disclosure pertains will understand that various modifications are possible within the scope of the technical spirit of the disclosure.

What is claimed is:

1. A display device, comprising:
a plurality of emission areas;
a non-emission area proximate to the plurality emission areas;
a plurality of anode electrodes spaced apart from each other, wherein each of the plurality anode electrodes overlaps each of the plurality of emission areas and the non-emission area; and
a plurality of separators respectively disposed on the plurality of anode electrodes and overlapping the non-emission area.

2. The display device according to claim 1, wherein each of the plurality of separators surrounds at least one surface of each of the plurality of emission areas.

3. The display device according to claim 2, wherein each of the plurality of separators is proximate to three surfaces of each of the plurality of emission areas.

4. The display device according to claim 3, further comprising:
a pixel defining layer disposed on the plurality of anode electrodes and the plurality of separators and proximate to a remaining one surface of each of the plurality of emission areas;
a light emitting structure disposed on the plurality of anode electrodes, the plurality od separators, and the pixel defining layer; and
a cathode electrode disposed on the light emitting structure.

5. The display device according to claim 4, wherein each of the plurality of separators has a taper structure.

6. The display device according to claim 5, wherein an angle of the taper structure, with respect to a plane of the plurality of anode electrodes, is at least 50°.

7. The display device according to claim 5, wherein a thickness of the taper structure is greater than a thickness of the light emitting structure.

8. The display device according to claim 4, wherein each of the plurality of separators has an inverse taper structure that gets thicker farther away from the plurality of anode electrodes.

9. The display device according to claim 8, wherein a thickness of the inverse taper structure is greater than a thickness of the light emitting structure.

10. The display device according to claim 4, wherein the light emitting structure and/or the cathode electrode is split by the plurality of separators.

11. The display device according to claim 2, wherein each of the plurality of separators surrounds four surfaces of each of the plurality of emission areas.

12. The display device according to claim 11, further comprising:
a pixel defining layer disposed on the plurality of anode electrodes and the plurality of separators and surrounding the plurality of separators;
a light emitting structure disposed on the plurality of anode electrodes, the plurality of separators, and the pixel defining layer; and
a cathode electrode disposed on the light emitting structure.

13. The display device according to claim 12, wherein each of the plurality of separators has a taper structure.

14. The display device according to claim 13, wherein an angle of the taper structure, with respect to a plane of the plurality of anode electrodes, is at least 50°.

15. The display device according to claim 13, wherein a thickness of the taper structure is greater than a thickness of the light emitting structure.

16. The display device according to claim 12, wherein each of the plurality of separators has an inverse taper structure that gets thicker farther away from the plurality of anode electrodes.

17. The display device according to claim 13, wherein a thickness of the inverse taper structure is greater than a thickness of the light emitting structure.

18. The display device according to claim 12, wherein the light emitting structure and/or the cathode electrode is split by the plurality of separators.

19. The display device according to claim 1, wherein each of the plurality of separators includes an inorganic material.

20. A display device, comprising:
an emission area;
a non-emission area proximate to the emission area;
an anode electrode overlapping both the emission area and the non-emission area;
a light-emitting structure disposed on the anode electrode within the emission area;
a separator disposed on the anode electrode and separating the emission area from the non-emission area,
wherein the separator has a shape that is wider farther from the anode electrode, and
wherein the separator is disposed at a discontinuity of a cathode electrode and/or a light-emitting structure.
